(19) United States
(12) Patent Application Publication
(10) Pub. No.: US 2022/0149833 A1
(43) Pub. Date: May 12, 2022

(54) DRIVE CAPABILITY SWITCHING CIRCUIT FOR SEMICONDUCTOR ELEMENT AND DRIVE DEVICE FOR SEMICONDUCTOR ELEMENT

(71) Applicant: FUJI ELECTRIC CO., LTD., Kawasaki-shi (JP)

(72) Inventor: Kenshi TERASHIMA, Matsumoto-city (JP)

(73) Assignee: FUJI ELECTRIC CO., LTD., Kawasaki-shi (JP)

(21) Appl. No.: 17/583,959

(22) Filed: Jan. 25, 2022

Related U.S. Application Data
(63) Continuation of application No. PCT/JP2020/047684, filed on Dec. 21, 2020.

(30) Foreign Application Priority Data
Feb. 19, 2020 (JP) 2020-026652

(51) Int. Cl. H03K 17/16; H02M 1/08

(52) U.S. Cl. CPC H03K 17/168; H02P 27/08; H02M 1/08

(57) ABSTRACT

An object of the present invention is to provide a drive capability switching circuit for a semiconductor element and a drive device for a semiconductor element capable of suppressing a radiation noise while reducing a loss occurred in switching of the semiconductor element. An IGBT drive capability switching circuit includes a gate voltage detection unit that detects a voltage level of a gate voltage based on a gate signal which is input to an IGBT in a mirror period, and a gate signal switching unit that switches a voltage level of the gate signal based on the voltage level detected by the gate voltage detection unit.

### TECHNICAL FIELD

The present invention relates to a drive capability switching circuit for a semiconductor element and a drive device for a semiconductor element that are applied to a power converter or the like.

### BACKGROUND ART

In the related art, an intelligent power module (IPM) obtained by integrating an insulated gate bipolar transistor (IGBT) for power conversion, an FWD chip, and an IC for drive and protection functions into one package is known.

As a gate circuit for driving an IGBT, there is known a gate drive circuit that receives an input signal from the outside and charges a gate of the IGBT with a constant current by an operational amplifier and a current mirror circuit (for example, PTL 1).

### CITATION LIST

### Patent Literature

PTL 1: WO 2009/044602

### SUMMARY OF INVENTION

### Technical Problem

As a characteristic of the IGBT, a voltage gradient dv/dt, which is a gradient of a collector-emitter voltage when the IGBT is switched, tends to be sharp when the IGBT is in a low current period. In the IGBT, as a change amount in the voltage gradient dv/dt is larger, a radiation noise is likely to occur, and this causes electromagnetic waves. In the related art, in order to suppress the radiation noise of the IGBT, there is provided a countermeasure of decreasing the voltage gradient dv/dt in a low current period by decreasing a drive capability of the IGBT. However, when the voltage gradient dv/dt of the IGBT in a low current period is decreased, the voltage gradient dv/dt of the IGBT after the low current period is further decreased. For this reason, there is a problem that a loss occurred in switching of the IGBT increases.

An object of the present invention is to provide a drive capability switching circuit for a semiconductor element and a drive device for a semiconductor element capable of suppressing a radiation noise while reducing a loss occurred in switching of the semiconductor element.

### Solution to Problem

In order to achieve the object, according to an aspect of the present invention, there is provided a drive capability switching circuit for a semiconductor element, the circuit including: a detection unit configured to detect a voltage level of a gate voltage based on a gate signal input to a voltage-controlled semiconductor element in a mirror period; and a switching unit configured to switch a voltage level of the gate signal based on the voltage level detected by the detection unit.

Further, in order to achieve the object, according to another aspect of the present invention, there is provided a drive device for a semiconductor element, the device including: a gate signal generation unit configured to generate a gate signal for driving a voltage-controlled semiconductor element; and a drive capability switching circuit for a semiconductor element, the circuit including a detection unit configured to detect a voltage level of a gate voltage based on the gate signal in a mirror period and a switching unit configured to switch a voltage level of the gate signal based on the voltage level detected by the detection unit.

### Advantageous Effects of Invention

According to an aspect of the present invention, it is possible to suppress a radiation noise while reducing a loss occurred in switching of a semiconductor element.

### BRIEF DESCRIPTION OF DRAWINGS

FIG. 1 is a circuit diagram illustrating a schematic configuration of a power converter including a drive capability switching circuit for a semiconductor element and a drive device for a semiconductor element according to an embodiment of the present invention;

FIG. 2 is a circuit diagram illustrating an example of the drive capability switching circuit for a semiconductor element and the drive device for a semiconductor element according to the embodiment of the present invention;

FIG. 3 is a diagram illustrating an example of a timing chart of the drive capability switching circuit for a semiconductor element according to the embodiment of the present invention;

FIG. 4 is a circuit diagram illustrating an example of a drive device for a semiconductor element in the related art as a comparative example;

FIG. 5 is a diagram illustrating an example of an operation waveform of an IGBT to be driven by the drive capability switching circuit for a semiconductor element and the drive device for a semiconductor element according to the embodiment of the present invention; and

FIG. 6 is a diagram explaining effects of the drive capability switching circuit for a semiconductor element and the drive device for a semiconductor element according to the embodiment of the present invention, and is a graph illustrating an example of a voltage gradient with respect to a collector current of an IGBT to be driven.

### DESCRIPTION OF EMBODIMENTS

An embodiment of the present invention exemplifies a device or a method for embodying a technical idea of the present invention. In the technical idea of the present invention, materials, shapes, structures, dispositions, and the like of components are not limited to the following description. The technical idea of the present invention may be modified in various ways within a technical scope defined by the claims.

(Power Converter)

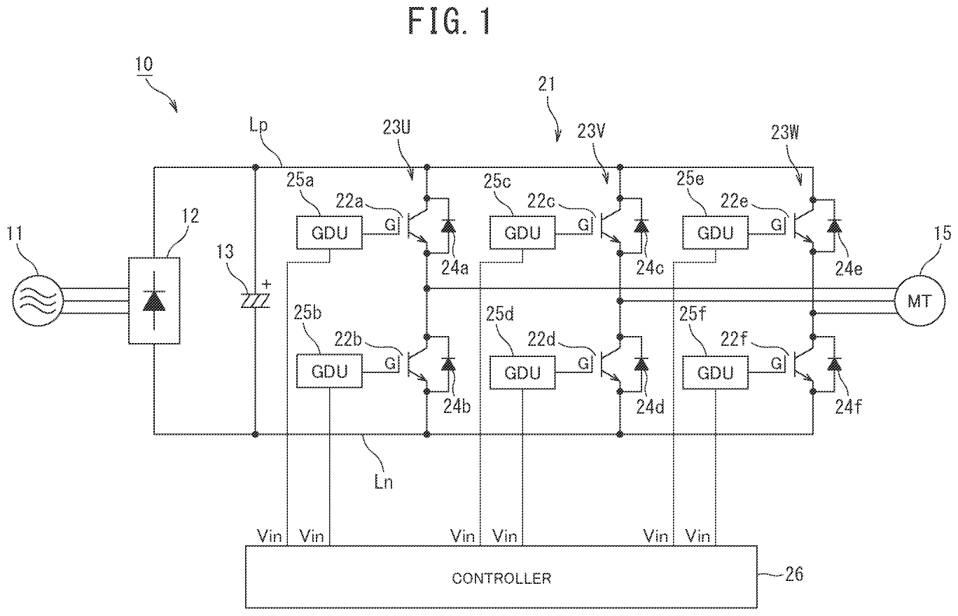

A power converter 10 including a drive capability switching circuit for a semiconductor element and a drive device for a semiconductor element according to the present embodiment will be described with reference to FIG. 1.

As illustrated in FIG. 1, the power converter 10 is connected to a three-phase AC power supply 11. The power converter 10 includes a rectifier circuit 12 that full-wave rectifies a three-phase AC power input from the three-phase AC power supply 11, and a smoothing capacitor 13 that smooths the power rectified by the rectifier circuit 12. Although not illustrated, the rectifier circuit 12 is configured with six diodes connected in a full bridge configuration or six switching elements connected in a full bridge configuration.

A positive electrode line Lp is connected to a positive electrode output terminal of the rectifier circuit 12, and a negative electrode line Ln is connected to a negative electrode output terminal of the rectifier circuit 12. The smoothing capacitor 13 is connected between the positive electrode line Lp and the negative electrode line Ln. Further, the power converter 10 includes an inverter circuit 21 that converts a DC voltage applied between the positive electrode line Lp and the negative electrode line Ln into a three-phase AC voltage. The inverter circuit 21 includes, for example, insulated gate bipolar transistors (an example of voltage-controlled semiconductor elements) 22a, 22c, and 22e as voltage-controlled semiconductor elements that are included in an upper arm portion connected to the positive electrode line Lp, and IGBTs 22b, 22d, and 22f that are included in a lower arm portion connected to the negative electrode line Ln. Hereinafter, the insulated gate bipolar transistor may be referred to as an “IGBT”.

The IGBT 22a and the IGBT 22b are connected in series between the positive electrode line Lp and the negative electrode line Ln, and are included in a U-phase output arm 23U. The IGBT 22c and the IGBT 22d are connected in series between the positive electrode line Lp and the negative electrode line Ln, and are included in a V-phase output arm 23V. The IGBT 22e and the IGBT 22f are connected in series between the positive electrode line Lp and the negative electrode line Ln, and are included in a W-phase output arm 23W.

Flyback diodes 24a to 24f are respectively connected to the IGBTs 22a to 22f in reversely parallel. That is, cathodes of the flyback diodes 24a to 24f are respectively connected to collectors of the IGBTs 22a to 22f serving as high potential electrodes, and anodes of the flyback diodes 24a to 24f are respectively connected to emitters of the IGBTs 22a to 22f serving as low potential electrodes.

A connection portion of the IGBT 22a and the IGBT 22b, a connection portion of the IGBT 22c and the IGBT 22d, and a connection portion of the IGBT 22e and the IGBT 22f are respectively connected to a three-phase AC motor 15 serving as an inductive load.

Further, the power converter 10 includes gate drive devices (an example of drive devices for semiconductor elements) 25a to 25f that individually control switching operations of the IGBTs 22a to 22f. In FIG. 1, the gate drive device is illustrated as “GDU”. Output terminals of the gate drive devices 25a to 25f are respectively connected to gates of the IGBTs 22a to 22f serving as control terminals.

The inverter circuit 21 includes a three-phase full bridge circuit in which the U-phase output arm 23U, the V-phase output arm 23V, and the W-phase output arm 23W are connected in parallel, the gate drive devices 25a and 25b for controlling a switching operation of the U-phase output arm 23U, the gate drive devices 25c and 25d for controlling a switching operation of the V-phase output arm 23V, and the gate drive devices 25e and 25f for controlling a switching operation of the W-phase output arm 23W.

The power converter 10 includes a controller 26 that controls the gate drive devices 25a to 25f. The controller 26 is configured to individually output, for example, a pulse input signal Vin to each of the gate drive devices 25a to 25f. Therefore, the controller 26 drives the IGBTs 22a to 22f according to, for example, pulse width modulation (PWM) by controlling the gate drive devices 25a to 25f.

(Drive Capability Switching Circuit for Semiconductor Element and Drive Device for Semiconductor Element)

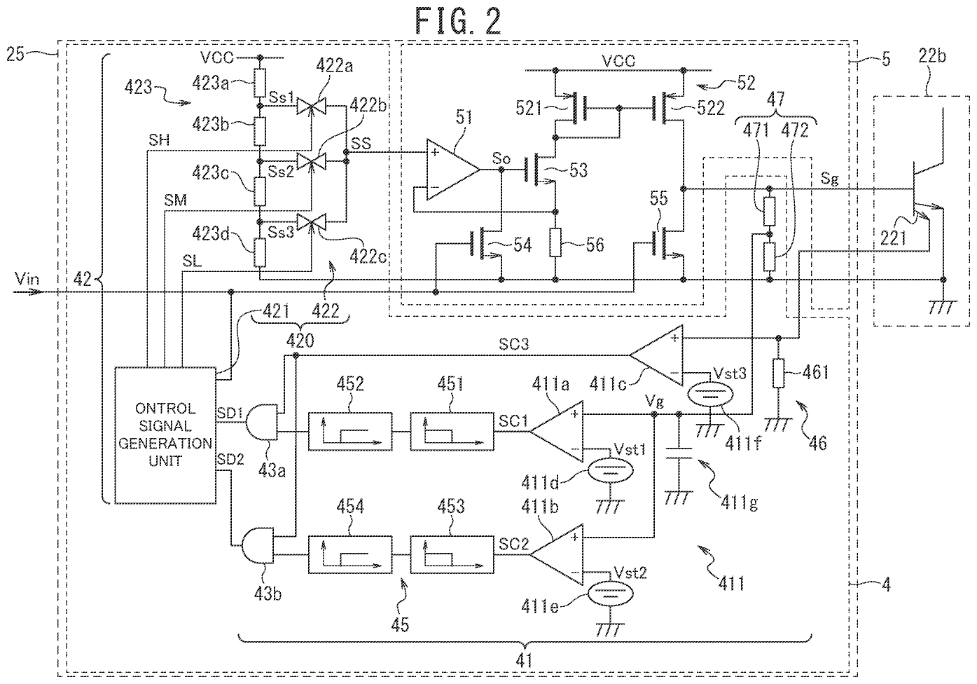

Next, a drive capability switching circuit for a semiconductor element and a drive device for a semiconductor element according to the present embodiment will be described with reference to FIG. 1 and FIG. 2 by taking the gate drive device 25b as an example. The gate drive devices 25a, 25c, 25d, 25e, and 25f have the same configuration as the gate drive device 25b. Further, each of the IGBTs 22a to 22f has the same configuration as each other, and has a current sense terminal (details will be described later) which is not illustrated in FIG. 1.

As illustrated in FIG. 2, the gate drive device 25b includes a gate signal generation unit 5 that generates a gate signal for driving the IGBT 22b, and an IGBT drive capability switching circuit (an example of a drive capability switching circuit for a semiconductor element) 4. The gate drive device 25b is configured with an integrated circuit (IC). The gate signal generation unit 5 and the IGBT drive capability switching circuit 4 are integrated and formed on one IC chip. The IGBT drive capability switching circuit 4 includes a gate voltage detection unit (an example of a detection unit) 41 that detects a voltage level of a gate voltage based on a gate signal which is input to the IGBT 22b in a mirror period, and a gate signal switching unit (an example of a switching unit) 42 that switches a voltage level of the gate signal based on the voltage level detected by the gate voltage detection unit 41. The gate voltage based on the gate signal which is input to the IGBT 22b is a gate-emitter voltage of the IGBT 22b.

As illustrated in FIG. 2, the gate signal generation unit 5 has an amplifier 51 to which a switching signal SS output from the IGBT drive capability switching circuit 4 is input, and a transistor 53 having a gate to which an output signal So output from the amplifier 51 is input. The amplifier 51 is configured with, for example, an operational amplifier. The transistor 53 is configured with, for example, an N-type MOS transistor. An output terminal of the amplifier 51 is connected to the gate of the transistor 53. A non-inversion input terminal (+) of the amplifier 51 is connected to the IGBT drive capability switching circuit 4.

The gate signal generation unit 5 has a current mirror circuit 52 connected to a drain of the transistor 53, and a resistance element 56 connected to a source of the transistor 53. One terminal of the resistance element 56 is connected to the source of the transistor 53, and the other terminal of the resistance element 56 is connected to a ground serving as a reference potential. A connection portion between the source of the transistor 53 and one terminal of the resistance element 56 is connected to an inversion input terminal (−) of the amplifier 51.

The current mirror circuit 52 has a transistor 521 and a transistor 522 of which gates are connected to each other. Each of the transistor 521 and the transistor 522 is configured with, for example, a P-type MOS transistor. A source of the transistor 521 is connected to a power supply output terminal from which a power supply voltage VCC is output, and a drain of the transistor 521 is connected to the gates of the transistors 521 and 522 and the drain of the transistor 53.

The gate signal generation unit 5 has a transistor 54 and a transistor 55 of which gates are connected to the controller 26 (not illustrated in FIG. 2, refer to FIG. 1). Each of the transistor 54 and the transistor 55 is configured with, for example, an N-type MOS transistor. The input signal Vin output from the controller 26 is input to each of the gates of the transistor 54 and the transistor 55. Thus, an ON/OFF state (conduction/non-conduction state) of each of the transistor 54 and the transistor 55 is controlled by the controller 26. The transistor 54 and the transistor 55 enter into an ON state (conduction state) in a case where a voltage level of the input signal Vin is a high level, and enter into an OFF state (non-conduction state) in a case where the voltage level of the input signal Vin is a low level. The transistor 54 and the transistor 55 are controlled to enter into an ON/OFF state in synchronization with each other, and are controlled to switch from an ON state to an OFF state or from an OFF state to an ON state almost at the same time.

A source of the transistor 54 and a source of the transistor 55 are connected to each other. Further, the source of the transistor 54 and the source of the transistor 55 are connected to the other terminal of the resistance element 56 and the ground serving as the reference potential. A drain of the transistor 54 is connected to a connection portion between the output terminal of the amplifier 51 and the gate of the transistor 53. A drain of the transistor 55 is connected to the drain of the transistor 522. A connection portion between the drain of the transistor 55 and the drain of the transistor 522 is connected to the gate of the IGBT 22b.

In a case where the voltage level of the input signal Vin is a high level, the gate signal generation unit 5 having the configuration enters into a non-operation state and does not output a gate signal Sg to the IGBT 22b. More specifically, in a case where the input signal Vin having a high voltage level is input to the gate of each of the transistor 54 and the transistor 55, each of the transistor 54 and the transistor 55 enters into an ON state. Since the gate of the transistor 53 is connected to the ground via the transistor 54, the transistor 53 enters into an OFF state. Therefore, the current mirror circuit 52 does not pass a current toward the ground, and thus the gate signal Sg is not output to the gate of the IGBT 22b. Further, the gate of the IGBT 22b is connected to the ground via the transistor 55, and thus the IGBT 22b enters into a non-operation state.

On the other hand, in a case where the voltage level of the input signal Vin is a low level, the gate signal generation unit 5 enters into an operation state and outputs agate signal Sg to the IGBT 22b. More specifically, in a case where the input signal Vin having a low voltage level is input to the gate of each of the transistor 54 and the transistor 55, each of the transistor 54 and the transistor 55 enters into an OFF state. Thus, the gate of the transistor 53 is electrically cut off from the ground by the transistor 54. Therefore, the output signal So of the amplifier 51 is input to the gate of the transistor 53, and thus the transistor 53 enters into an ON state. The transistor 53 is feedback-controlled by the amplifier 51 such that the voltage of the source becomes the same voltage as the voltage of a switching signal Sc input to the amplifier 51. The amplifier 51 and the transistor 53 function as a constant current source of which a current value is determined by the voltage level of the switching signal Sc. As a result, a current corresponding to the voltage level of the switching signal Sc flows from the current mirror circuit 52 toward the ground via the transistor 53 and the resistance element 56. A current corresponding to the voltage level of the switching signal Sc also flows through the transistor 522 of the current mirror circuit 52. Since the transistor 55 is in a non-conduction state (OFF state), a part of the current flowing from the transistor 522 flows toward the gate of the IGBT 22b, as a gate current. Therefore, the gate signal Sg based on the voltage level of the switching signal Sc is input to the gate of the IGBT 22b. As a result, the IGBT 22b is driven with a drive capability according to a gate voltage Vg based on the gate signal which is input to the gate.

As illustrated in FIG. 2, the gate voltage detection unit 41 provided in the IGBT drive capability switching circuit 4 has a ladder resistance circuit 47 connected between the gate and the emitter of the IGBT 22b. The ladder resistance circuit 47 has a resistance element 471 and a resistance element 472 that are connected in series between the gate and the emitter of the IGBT 22b. One terminal of the resistance element 471 is connected to the gate of the IGBT 22b, the drain of the transistor 522, and the drain of the transistor 55. The other terminal of the resistance element 471 is connected to one terminal of the resistance element 472. The other terminal of the resistance element 472 is connected to the emitter of the IGBT 22b, the sources of the transistors 54 and 55, the other terminal of the resistance element 56, and the ground. Thus, the other part of the current flowing from the transistor 522 flows through the ladder resistance circuit 47. The gate voltage detection unit 41 is configured to detect, as the gate voltage Vg, a voltage drop in the ladder resistance circuit 47 due to a flow of the current.

As illustrated in FIG. 2, the gate voltage detection unit 41 included in the IGBT drive capability switching circuit 4 has a comparison unit 411 that compares the gate voltage in the mirror period with a setting voltage and compares a sense voltage with a setting voltage, the sense voltage being based on a sense current flowing through a current sense terminal 221 of the IGBT 22b. Further, the gate signal switching unit 42 included in the IGBT drive capability switching circuit 4 has a switching signal generation unit (an example of a signal generation unit) 423 that generates a plurality of selection signals (examples of a plurality of signals) Ss1, Ss2, and Ss3 having different voltage levels, and a selection unit 420 that selects a voltage level of the gate signal from the voltage levels of the plurality of selection signals Ss1, Ss2, and Ss3 based on a comparison result of the comparison unit 411.

The comparison unit 411 has a first comparator 411a that compares the gate voltage in the mirror period with a first setting voltage Vst1 as a setting voltage, a second comparator 411b that compares the gate voltage in the mirror period with a second setting voltage Vst2 as a setting voltage, and a third comparator 411c that compares the sense voltage with a third setting voltage Vst3 as a setting voltage. Each of the first comparator 411a, the second comparator 411b, and the third comparator 411c is configured with, for example, an operational amplifier.

Further, the comparison unit 411 has a first setting voltage generation unit 411d that generates the first setting voltage Vst1, a second setting voltage generation unit 411e that generates the second setting voltage Vst2, and a third setting voltage generation unit 411f that generates the third setting voltage Vst3. Each of the first setting voltage generation unit 411d, the second setting voltage generation unit 411e, and the third setting voltage generation unit 411f is configured with, for example, a DC power supply. The first setting voltage Vst1 is set to a voltage lower than the second setting voltage Vst2. Further, the first setting voltage Vst1 and the second setting voltage Vst2 are set to be lower than the gate voltage in the mirror period in a case where a current corresponding to a collector current of an absolute maximum rating is flowing through the IGBT 22b. The first setting voltage Vst1 is set to be lower than the gate voltage in the mirror period in a case where a current corresponding to, for example, 10% of a collector current of an absolute maximum rating is flowing through the IGBT 22b. The second setting voltage Vst2 is set to be lower than the gate voltage in the mirror period in a case where a current corresponding to, for example, 90% of a collector current of an absolute maximum rating is flowing through the IGBT 22b. The third setting voltage Vst3 is set to a voltage lower than the sense voltage of the gate voltage (that is, the gate-emitter voltage) of the IGBT 22b in the mirror period and higher than the sense voltage of the gate voltage of the IGBT 22b in a period other than the mirror period.

A non-inversion input terminal (+) of the first comparator 411a is connected to a connection portion between the resistance element 471 and the resistance element 472 which are included in the ladder resistance circuit 47. An inversion input terminal (−) of the first comparator 411a is connected to a positive electrode terminal of the first setting voltage generation unit 411d. A negative electrode terminal of the first setting voltage generation unit 411d is connected to the ground serving as the reference potential. Thus, the first comparator 411a compares the gate voltage Vg with the first setting voltage Vst1, and outputs a first comparison signal SC1 having a low level in a case where the gate voltage Vg is lower than the first setting voltage Vst1. On the other hand, the first comparator 411a outputs a first comparison signal SC1 having a high level in a case where the gate voltage Vg is higher than the first setting voltage Vst1.

A non-inversion input terminal (+) of the second comparator 411b is connected to a connection portion between the resistance element 471 and the resistance element 472 which are included in the ladder resistance circuit 47. An inversion input terminal (−) of the second comparator 411b is connected to a positive electrode terminal of the second setting voltage generation unit 411e. A negative electrode terminal of the second setting voltage generation unit 411e is connected to the ground serving as the reference potential. Thus, the second comparator 411b compares the gate voltage Vg with the second setting voltage Vst2, and outputs a second comparison signal SC2 having a low level in a case where the gate voltage Vg is lower than the second setting voltage Vst2. On the other hand, the second comparator 411b outputs a second comparison signal SC2 having a high level in a case where the gate voltage Vg is higher than the second setting voltage Vst2.

The comparison unit 411 has a capacitor 411g provided between the connection portion between the resistance element 417 and the resistance element 472 of the ladder resistance circuit 47 and the ground. One electrode of the capacitor 411g is connected to the connection portion, and the other electrode of the capacitor 411g is connected to the ground. The capacitor 411g is provided to prevent or reduce a change in the gate voltage which is input from the ladder resistance circuit 47 due to an influence of noise or the like. Thus, the comparison unit 411 is capable of preventing a malfunction of the first comparator 411a and a malfunction of the second comparator 411b.

The gate voltage detection unit 41 has a current detection unit 46 that detects, as a sense voltage, the sense current flowing through the current sense terminal 221 of the IGBT 22b. The current detection unit 46 has a resistance element 461 connected between the current sense terminal 221 of the IGBT 22b and the ground serving as the reference potential. The current detection unit 46 outputs, as a sense voltage, a sense current from a connection portion between the current sense terminal 221 of the IGBT 22b and the resistance element 461.

A non-inversion input terminal (+) of the third comparator 411c is connected to the connection portion between the current sense terminal 221 and the resistance element 461. An inversion input terminal (−) of the third comparator 411c is connected to a positive electrode terminal of the third setting voltage generation unit 411f. A negative electrode terminal of the third setting voltage generation unit 411f is connected to the ground. Thus, the third comparator 411c compares the sense voltage with the third setting voltage Vst3, and outputs a third comparison signal SC3 having a high level in a case where the sense voltage is higher than the third setting voltage Vst3. On the other hand, the third comparator 411c outputs a third comparison signal SC3 having a low level in a case where the sense voltage is higher than the third setting voltage Vst3.

The comparison unit 411 may have a capacitor connected between the current sense terminal 221 of the IGBT 22b and the ground. Thus, the comparison unit 411 is capable of preventing a malfunction of the third comparator 411c by preventing or reducing a change in the sense voltage due to an influence of noise or the like.

The gate voltage detection unit 41 has a filter unit 45 provided on the output side of the comparison unit 411. The filter unit 45 has a low-pass filter 451 having an input terminal connected to an output terminal of the first comparator 411a, and a high-pass filter 452 having an input terminal connected to an output terminal of the low-pass filter 451. The low-pass filter 451 removes a high frequency superimposed on the first comparison signal SC1. Further, the high-pass filter 452 removes a low frequency superimposed on the first comparison signal SC1 from which the high frequency is removed by the low-pass filter 451.

The filter unit 45 has a low-pass filter 453 having an input terminal connected to an output terminal of the second comparator 411b, and a high-pass filter 454 having an input terminal connected to an output terminal of the low-pass filter 453. The low-pass filter 453 removes a high frequency superimposed on the second comparison signal SC2. Further, the high-pass filter 454 removes a low frequency superimposed on the second comparison signal SC2 from which the high frequency is removed by the low-pass filter 453. In this way, the filter unit 45 is capable of removing noise components superimposed on the first comparison signal SC1 and the second comparison signal SC2.

Further, the filter unit 45 may have a low-pass filter having an input terminal connected to an output terminal of the third comparator 411c, and a high-pass filter having an input terminal connected to an output terminal of the low-pass filter. The low-pass filter removes a high frequency superimposed on the third comparison signal SC3, and the high-pass filter removes a low frequency superimposed on the third comparison signal SC3 from which the high frequency is removed by the low-pass filter.

The gate voltage detection unit 41 has a first logic circuit 43a that outputs, to the selection unit 420, a first detection signal SD1 obtained by performing a logic operation on the first comparison signal SC1 input from the first comparator 411a and the third comparison signal SC3 input from the third comparator 411c. Further, the gate voltage detection unit 41 has a second logic circuit 43b that outputs, to the selection unit 420, a second detection signal SD2 obtained by performing a logic operation on the second comparison signal SC2 input from the second comparator 411b and the third comparison signal SC3. Each of the first logic circuit 43a and the second logic circuit 43b is configured with, for example, a logic product circuit (AND gate).

One input terminal of the first logic circuit 43a is connected to an output terminal of the high-pass filter 452, and the other input terminal of the first logic circuit 43a is connected to the output terminal of the third comparator 411c. Thus, the first comparison signal SC1 from which noise is removed bypassing through the low-pass filter 451 and the high-pass filter 452 is input to the first logic circuit 43a. The first logic circuit 43a is configured to generate the first detection signal SD1 by performing a logic product operation on signals which are input using the voltage level of the first comparison signal SC1 and the voltage level of the third comparison signal SC3.

One input terminal of the second logic circuit 43b is connected to an output terminal of the high-pass filter 454, and the other input terminal of the second logic circuit 43b is connected to the output terminal of the third comparator 411c. Thus, the second comparison signal SC2 from which noise is removed bypassing through the low-pass filter 453 and the high-pass filter 454 is input to the second logic circuit 43b. The second logic circuit 43b is configured to generate the second detection signal SD2 by performing a logic product operation on signals which are input using the voltage level of the second comparison signal SC2 and the voltage level of the third comparison signal SC3.

As illustrated in FIG. 2, a switching signal generation unit 423 included in the gate signal switching unit 42 is configured with, for example, a ladder resistance circuit. The switching signal generation unit 423 has four resistance elements 423a, 423b, 423c, and 423d connected in series between the power supply output terminal from which the power supply voltage VCC is output and the ground serving as the reference potential. One terminal of the resistance element 423a is connected to the power supply output terminal, and the other terminal of the resistance element 423a is connected to one terminal of the resistance element 423b. The other terminal of the resistance element 423b is connected to one terminal of the resistance element 423c. The other terminal of the resistance element 423c is connected to one terminal of the resistance element 423d. The other terminal of the resistance element 423d is connected to the ground.

A connection portion between the resistance element 423a and the resistance element 423b serves as an output terminal fora selection signal Ss1. A connection portion between the resistance element 423b and the resistance element 423c serves as an output terminal for a selection signal Ss2. A connection portion between the resistance element 423c and the resistance element 423d serves as an output terminal for a selection signal Ss3. A resistance value of each of the resistance elements 423a, 423b, 423c, and 423d is set such that a voltage level of each of the selection signal Ss1, the selection signal Ss2, and the selection signal Ss3 has a desired voltage value.

As illustrated in FIG. 2, the selection unit 420 has a control signal generation unit 421 that generates a selection control signal (an example of a control signal) SL, SM, and SH for controlling selection of any one of a plurality of selection signals Ss1, Ss2, and Ss3 using the input signal Vin which is input to the gate signal generation unit 5 for generating the gate signal Sg, the first detection signal SD1, and the second detection signal SD2. The selection unit 420 has a switch circuit 422 that outputs, to the gate signal generation unit 5, any one of the plurality of selection signals Ss1, Ss2, and Ss3 input from the switching signal generation unit 423 by being controlled by the selection control signals SL, SM, and SH.

The control signal generation unit 421 has, for example, three signal input terminals and three signal output terminals. An output terminal of the first logic circuit 43a is connected to a first input terminal as one signal input terminal of the three signal input terminals. An output terminal of the second logic circuit 43b is connected to a second input terminal as another signal input terminal of the three signal input terminals. An output terminal of the controller 26 for outputting the input signal Vin is connected to a third input terminal as the other signal input terminal of the three signal input terminals.

The selection control signal SL is output from a first output terminal as one signal output terminal of the three signal output terminals of the control signal generation unit 421. The selection control signal SM is output from a second output terminal as another signal output terminal of the three signal output terminals. The selection control signal SH is output from a third output terminal as the other signal output terminal of the three signal output terminals. The control signal generation unit 421 is configured to determine voltage levels of the selection control signals SL, SM, and SH based on the voltage level of the first detection signal SD1 and the voltage level of the second detection signal SD2 at a timing when the input signal Vin falls (at a timing of turn-off). Details of an operation of the control signal generation unit 421 will be described later.

The switch circuit 422 has a switching element 422a, a switching element 422b, and a switching element 422c. Each of the switching element 422a, the switching element 422b, and the switching element 422c is configured with, for example, an analog switch.

An input terminal of the switching element 422a is connected to a connection portion between the resistance element 423a and the resistance element 423b. Thus, the selection signal Ss1 is input to the input terminal of the switching element 422a. An input terminal of the switching element 422b is connected to a connection portion between the resistance element 423b and the resistance element 423c. Thus, the selection signal Ss2 is input to the input terminal of the switching element 422b. An input terminal of the switching element 422c is connected to a connection portion between the resistance element 423c and the resistance element 423d. Thus, the selection signal Ss3 is input to the input terminal of the switching element 422c. Output terminals of the switching element 422a, the switching element 422b, and the switching element 422c are connected to each other, and are connected to a non-inversion input terminal (+) of the amplifier 51 included in the gate signal generation unit 5.

A control terminal for controlling an ON/OFF (conduction/non-conduction) state of the switching element 422a is connected to the first output terminal of the control signal generation unit 421. Thus, the selection control signal SL is input to the control terminal of the switching element 422a. For example, the switching element 422a enters into an ON state (conduction state) in a case where the selection control signal SL having a high level is input to the control terminal, and outputs, from the output terminal, the selection signal Ss1 which is input to the input terminal. For example, the switching element 422a enters into an OFF state (non-conduction state) in a case where the selection control signal SL having a low level is input to the control terminal, and does not output, from the output terminal, the selection signal Ss1 which is input to the input terminal.

A control terminal for controlling an ON/OFF (conduction/non-conduction) state of the switching element 422b is connected to the second output terminal of the control signal generation unit 421. Thus, the selection control signal SM is input to the control terminal of the switching element 422b. For example, the switching element 422b enters into an ON state (conduction state) in a case where the selection control signal SM having a high level is input to the control terminal, and outputs, from the output terminal, the selection signal Ss2 which is input to the input terminal. For example, the switching element 422b enters into an OFF state (non-conduction state) in a case where the selection control signal SL having a low level is input to the control terminal, and does not output, from the output terminal, the selection signal Ss2 which is input to the input terminal.

A control terminal for controlling an ON/OFF (conduction/non-conduction) state of the switching element 422c is connected to the third output terminal of the control signal generation unit 421. Thus, the selection control signal SH is input to the control terminal of the switching element 422c. For example, the switching element 422c enters into an ON state (conduction state) in a case where the selection control signal SH having a high level is input to the control terminal, and outputs, from the output terminal, the selection signal Ss3 which is input to the input terminal. For example, the switching element 422c enters into an OFF state (non-conduction state) in a case where the selection control signal SH having a low level is input to the control terminal, and does not output, from the output terminal, the selection signal Ss3 which is input to the input terminal.

Although details will be described later, the control signal generation unit 421 operates such that the voltage level of any one of the selection control signal SL, the selection control signal SM, and the selection control signal SH is set to a high level and the other voltage levels are set to a low level. Thus, the switch circuit 422 outputs, as the switching signal SS, any one of the selection signals Ss1, Ss2, and Ss3 input from the switching signal generation unit 423, to the amplifier 51. The switching elements 422a, 422b, and 422c are in a high impedance state in a case where the switching elements 422a, 422b, and 422c enter into an OFF state (non-conduction state). Thus, the switch circuit 422 is capable of preventing the other switching signals from interfering with the switching signal selected by the control of the control signal generation unit 421. Therefore, the IGBT drive capability switching circuit 4 is capable of outputting a desired switching signal SS based on the gate voltage to the gate signal generation unit 5.

(Operations of Drive Capability Switching Circuit for Semiconductor Element and Drive Device for Semiconductor Element)

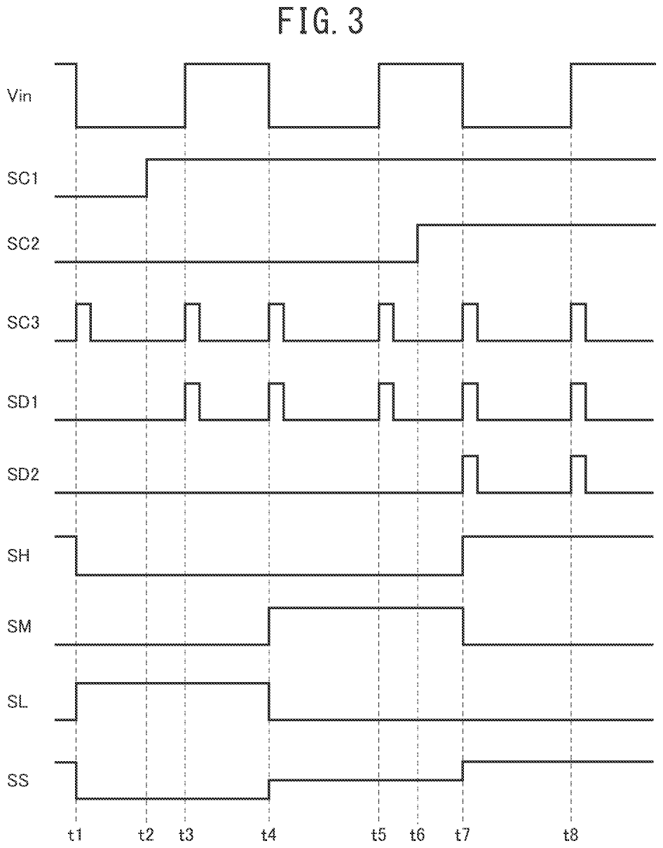

Next, operations of the drive capability switching circuit for the semiconductor element and the drive device for the semiconductor element according to the present embodiment will be described using FIG. 3 with reference to FIG. 2. First, a relationship between inputs and outputs of the control signal generation unit 421 will be described with reference to Table 1.

Table 1 is a truth table illustrating a relationship between inputs and outputs of the control signal generation unit 421. In Table 1, “SD1” represents the first detection signal SD1 which is input to the control signal generation unit 421. In Table 1, “SD2” represents the second detection signal SD2 which is input to the control signal generation unit 421. In Table 1, “Vin” represents the input signal Vin which is input to the control signal generation unit 421. In Table 1, “SL” represents the selection control signal SL which is output from the control signal generation unit 421. In Table 1, “SM” represents the selection control signal SM which is output from the control signal generation unit 421. In Table 1, “SH” represents the selection control signal SH which is output from the control signal generation unit 421.

In Table 1, “L” indicated in a column of “SD1” represents that the voltage level of the first detection signal SD1 is a low level, and “H” indicated in a column of “SD1” represents that the voltage level of the first detection signal SD1 is a high level. In Table 1, “L” indicated in a column of “SD2” represents that the voltage level of the second detection signal SD2 is a low level, and “H” indicated in a column of “SD2” represents that the voltage level of the second detection signal SD2 is a high level. In Table 1, “↓” indicated in a column of “Vin” represents falling (turn-off) of the input signal Vin, and “−” indicated in a column of “Vin” represents a state of the input signal Vin other than falling.

In Table 1, “L” indicated in a column of “SL” represents that the voltage level of the selection control signal SL is a low level, “H” indicated in a column of “SL” represents that the voltage level of the selection control signal SL is a high level, and “Q” indicated in a column of “SL” represents that the voltage level of the selection control signal SL does not change (maintains a current state). In Table 1, “L” indicated in a column of “SM” represents that the voltage level of the selection control signal SM is a low level, “H” indicated in a column of “SM” represents that the voltage level of the selection control signal SM is a high level, and “Q” indicated in a column of “SM” represents that the voltage level of the selection control signal SM does not change (maintains a current state). In Table 1, “L” indicated in a column of “SH” represents that the voltage level of the selection control signal SH is a low level, “H” indicated in a column of “SH” represents that the voltage level of the selection control signal SH is a high level, and “Q” indicated in a column of “SH” represents that the voltage level of the selection control signal SH does not change (maintains a current state).

TABLE 1

| SD1 | SD2 | Vin | SL | SM | SH |
|---|---|---|---|---|---|
| L | L | ↓ | H | L | L |
| H | L | ↓ | L | H | L |
| H | H | ↓ | L | L | H |
| L | L | — | Q | Q | Q |
| H | L | — | Q | Q | Q |
| H | H | — | Q | Q | Q |

As indicated in Table 1, in a case where the voltage levels of the first detection signal SD1 and the second detection signal SD2 are both low levels, when the input signal Vin falls, the control signal generation unit 421 outputs the selection control signal SL having a high voltage level and outputs the selection control signals SM and SH having a low voltage level. Further, in a case where the voltage levels of the first detection signal SD1 and the second detection signal SD2 are both low levels, even when the input signal Vin rises, the control signal generation unit 421 outputs the selection control signals SL, SM, and SH of which the voltage levels are maintained. Therefore, in a state where the gate voltage Vg is lower than both of the first setting voltage Vst1 and the second setting voltage Vst2, when the input signal Vin falls, the control signal generation unit 421 outputs the selection control signal SL having a high voltage level.

As indicated in Table 1, in a case where the voltage level of the first detection signal SD1 is a high level and the voltage level of the second detection signal SD2 is a low level, when the input signal Vin falls, the control signal generation unit 421 outputs the selection control signal SM having a high voltage level and outputs the selection control signals SL and SH having a low voltage level. Further, in a case where the voltage level of the first detection signal SD1 is a high level and the voltage level of the second detection signal SD2 is a low level, even when the input signal Vin rises, the control signal generation unit 421 outputs the selection control signals SL, SM, and SH of which the voltage levels are maintained. Therefore, in a state where the gate voltage Vg is higher than the first setting voltage Vst1 and the gate voltage Vg is lower than the second setting voltage Vst2, when the input signal Vin falls, the control signal generation unit 421 outputs the selection control signal SM having a high voltage level.

As indicated in Table 1, in a case where the voltage levels of the first detection signal SD1 and the second detection signal SD2 are both high levels, when the input signal Vin falls, the control signal generation unit 421 outputs the selection control signal SH having a high voltage level and outputs the selection control signals SL and SM having a low voltage level. Further, in a case where the voltage levels of the first detection signal SD1 and the second detection signal SD2 are both high levels, even when the input signal Vin rises, the control signal generation unit 421 outputs the selection control signals SL, SM, and SH of which the voltage levels are maintained. Therefore, in a state where the gate voltage Vg in the mirror period is higher than both of the first setting voltage Vst1 and the second setting voltage Vst2, when the input signal Vin falls, the control signal generation unit 421 outputs the selection control signal SH having a high voltage level.

Next, operations of the IGBT drive capability switching circuit 4 and the gate drive device 25b will be described using FIG. 3 with reference to FIG. 2 by taking the gate drive device 25b as an example. The gate drive devices 25a, 25c, 25d, 25e, and 25f operate in the same manner as the gate drive device 25b, and the IGBT drive capability switching circuit included in each of the gate drive devices 25a, 25c, 25d, 25e, and 25f operates in the same manner as the IGBT drive capability switching circuit 4 included in the gate drive device 25b.

“Vin” illustrated in FIG. 3 represents a voltage waveform of the input signal Vin. “SC1” illustrated in FIG. 3 represents a voltage waveform of the first comparison signal SC1, “SC2” illustrated in FIG. 3 represents a voltage waveform of the second comparison signal SC2, and “SC3” illustrated in FIG. 3 represents a voltage waveform of the third comparison signal SC3. “SD1” illustrated in FIG. 3 represents a voltage waveform of the first detection signal SD1, and “SD2” illustrated in FIG. 3 represents a voltage waveform of the second detection signal SD2. “SH” illustrated in FIG. 3 represents a voltage waveform of the selection control signal SH, “SM” illustrated in FIG. 3 represents a voltage waveform of the selection control signal SM, and “SL” illustrated in FIG. 3 represents a voltage waveform of the selection control signal SL. “SS” illustrated in FIG. 3 represents a voltage waveform of the switching signal SS. A timing chart illustrated in FIG. 3 represents an elapse of time from left to right.

As illustrated in FIG. 3, for example, before a timing t1, the voltage level of the selection control signal SH is a high level. Thus, the gate drive device 25b operates in a state where the selection signal Ss1 (refer to FIG. 2) output from the switching element 422a is input, as the switching signal SS, to the amplifier 51 included in the gate signal generation unit 5.

As illustrated in FIG. 3, at the timing t1, when the input signal Vin input from the controller 26 (refer to FIG. 1) falls, the gate signal generation unit 5 outputs the gate signal to the IGBT 22b. Thus, the IGBT 22b operates and transitions from an OFF state to an ON state, and a collector current flows. The collector current flowing through the IGBT 22b at the timing t1 has, for example, a current amount smaller than 10% of the absolute maximum rating. Thus, the voltage level of each of the first comparison signal SC1 and the second comparison signal SC2 is a low level. Further, in the mirror period for which the IGBT 22b operates and the gate voltage Vg changes with a voltage gradient dv/dt, the voltage level of the third comparison signal SC3 is a high level. As a result, the voltage level of each of the first detection signal SD1 and the second detection signal SD2 is a low level. Thus, at the timing t1, the voltage level of the selection control signal SL is a high level, and the voltage levels of the selection control signals SM and SH are low levels. Therefore, the selection signal Ss3 (refer to FIG. 2) output from the switching element 422c is input, as the switching signal SS, to the amplifier 51.

At a timing t2 when a predetermined time is elapsed from the timing t1, the collector current flowing through the IGBT 22b has a current amount larger than 10% of the absolute maximum rating and smaller than 90% of the absolute maximum rating. Thus, as illustrated in FIG. 3, the voltage level of the first comparison signal SC1 transitions from a low level to a high level. However, the voltage level of the third comparison signal SC3 at the timing t2 is a low level, and thus the first detection signal SD1 maintains a low voltage level. As a result, the selection control signal SL is maintained at a high voltage level.

At a timing t3 when a predetermined time is elapsed from the timing t2, the input signal Vin which is input from the controller 26 rises, and thus the IGBT 22b does not operate and transitions from an ON state to an OFF state. In the mirror period for which the IBGT 22b does not operate and the gate voltage Vg changes with a voltage gradient dv/dt, the voltage level of the third comparison signal SC3 is a high level. Further, the voltage level of the first comparison signal SC1 is a high level, and thus the voltage level of the first detection signal SD1 transitions from a low level to a high level. However, at the timing when the input signal Vin rises, the control signal generation unit 421 maintains the voltage levels of the selection control signals SL, SM, and SH (refer to Table 1). As a result, at the timing t3, the voltage levels of the selection control signals SL, SM, and SH are maintained in the same state as the state at the timing t1. Therefore, the selection signal Ss3 output from the switching element 422c is continuously input, as the switching signal SS, to the amplifier 51.

As illustrated in FIG. 3, at a timing t4 when a predetermined time is elapsed from the timing t3, when the input signal Vin input from the controller 26 falls, the gate signal generation unit 5 outputs the gate signal to the IGBT 22b. Thus, the IGBT 22b operates again and transitions from an OFF state to an ON state, and a collector current flows. The collector current flowing through the IGBT 22b at the timing t4 has, for example, a current amount larger than 10% of the absolute maximum rating and smaller than 90% of the absolute maximum rating. Thus, the voltage level of the first comparison signal SC1 is a high level, and the voltage level of the second comparison signal SC2 is a low level. Further, in the mirror period for which the IBGT 22b operates and the gate voltage Vg changes with a voltage gradient dv/dt, the voltage level of the third comparison signal SC3 is a high level. As a result, the voltage level of the first detection signal SD1 is a high level, and the voltage level of the second detection signal SD2 is a low level. Thus, at the timing t4, the voltage level of the selection control signal SM is a high level, and the voltage levels of the selection control signals SL and SH are low levels. Therefore, the selection signal Ss2 (refer to FIG. 2) output from the switching element 422b is input, as the switching signal SS, to the amplifier 51.

At a timing t5 when a predetermined time is elapsed from the timing t4, the input signal Vin which is input from the controller 26 rises, and thus the IGBT 22b does not operate and transitions from an ON state to an OFF state. In the mirror period for which the IBGT 22b does not operate and the gate voltage Vg changes with a voltage gradient dv/dt, the voltage level of the third comparison signal SC3 is a high level. Further, the voltage level of the first comparison signal SC1 is a high level, and thus the voltage level of the first detection signal SD1 transitions from a low level to a high level. However, at the timing when the input signal Vin rises, the control signal generation unit 421 maintains the voltage levels of the selection control signals SL, SM, and SH. As a result, at the timing t5, the voltage levels of the selection control signals SL, SM, and SH are maintained in the same state as the state at the timing t4. Therefore, the selection signal Ss2 output from the switching element 422b is continuously input, as the switching signal SS, to the amplifier 51.

At a timing t6 when a predetermined time is elapsed from the timing t5, the collector current flowing through the IGBT 22b has a current amount larger than 90% of the absolute maximum rating. Thus, as illustrated in FIG. 3, the voltage level of the second comparison signal SC2 transitions from a low level to a high level. Further, the voltage level of the first comparison signal SC1 is maintained at a high level. However, the voltage level of the third comparison signal SC3 at the timing t6 is a low level, and thus the first detection signal SD1 and the second detection signal SD2 maintain a low voltage level. As a result, the selection control signal SM is maintained at a high voltage level.

As illustrated in FIG. 3, at a timing t7 when a predetermined time is elapsed from the timing t6, when the input signal Vin input from the controller 26 falls, the gate signal generation unit 5 outputs the gate signal to the IGBT 22b. Thus, the IGBT 22b operates again and transitions from an OFF state to an ON state, and a collector current flows.

The collector current flowing through the IGBT 22b at the timing t7 has, for example, a current amount larger than 90% of the absolute maximum rating. Thus, the voltage level of each of the first comparison signal SC1 and the second comparison signal SC2 is a high level. Further, in the mirror period for which the IBGT 22b operates and the gate voltage Vg changes with a voltage gradient dv/dt, the voltage level of the third comparison signal SC3 is a high level. As a result, the voltage level of each of the first detection signal SD1 and the second detection signal SD2 is a high level. Thus, at the timing t7, the voltage level of the selection control signal SH is a high level, and the voltage levels of the selection control signals SL and SM are low levels. Therefore, the selection signal Ss1 (refer to FIG. 2) output from the switching element 422a is input, as the switching signal SS, to the amplifier 51.

At a timing t8 when a predetermined time is elapsed from the timing t7, the input signal Vin which is input from the controller 26 rises, and thus the IGBT 22b does not operate and transitions from an ON state to an OFF state. In the mirror period for which the IBGT 22b does not operate and the gate voltage Vg changes with a voltage gradient dv/dt, the voltage level of the third comparison signal SC3 is a high level. Further, the voltage level of each of the first comparison signal SC1 and the second comparison signal SC2 is a high level, and thus the voltage level of each of the first detection signal SD1 and the second detection signal SD2 transitions from a low level to a high level. However, at the timing when the input signal Vin rises, the control signal generation unit 421 maintains the voltage levels of the selection control signals SL, SM, and SH. As a result, at the timing t8, the voltage levels of the selection control signals SL, SM, and SH are maintained in the same state as the state at the timing t7. Therefore, the selection signal Ss1 output from the switching element 422a is continuously input, as the switching signal SS, to the amplifier 51.

As described above, the IGBT drive capability switching circuit 4 according to the present embodiment is capable of changing the voltage level of the switching signal SS to be output to the gate signal generation unit 5 according to a current amount of the collector current flowing through the IGBT 22b. More specifically, in a low current period for which the current amount of the collector current flowing through the IGBT 22b is small, the IGBT drive capability switching circuit 4 outputs the switching signal SS having a low voltage level to the gate signal generation unit 5. Further, in a large current period for which the current amount of the collector current flowing through the IGBT 22b is large, the IGBT drive capability switching circuit 4 outputs the switching signal SS having a high voltage level to the gate signal generation unit 5. Therefore, the gate drive device 25b is capable of decreasing the voltage gradient dv/dt of the gate voltage Vg in a case where the collector current flowing through the IBGT 22b is small, and thus it is possible to suppress a radiation noise occurred in switching of the IGBT 22b. Further, the gate drive device 25b is capable of driving the IGBT 22b without decreasing the drive capability in a case where the collector current flowing through the IBGT 22b is large, and thus it is possible to suppress a loss occurred in switching of the IGBT 22b.

(Effects of Drive Capability Switching Circuit for Semiconductor Element and Drive Device for Semiconductor Element)

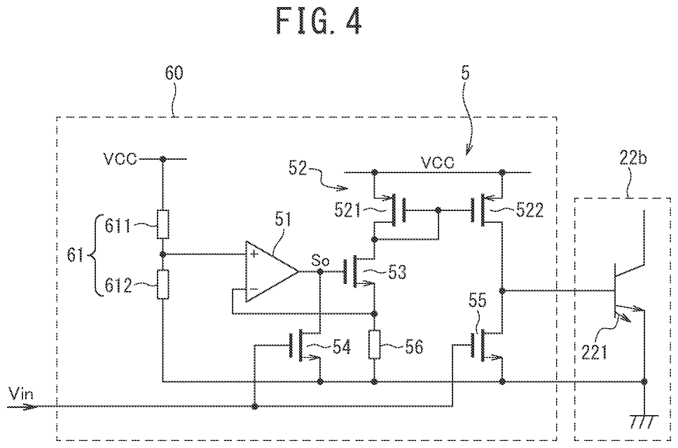

Next, effects of the drive capability switching circuit for the semiconductor element and the drive device for the semiconductor element according to the present embodiment will be described using FIG. 4 to FIG. 6 with reference to FIG. 2.

FIG. 4 is a circuit diagram of a gate drive device 60 in the related art. In components of the gate drive device 60, components having the same configurations and functions as the components of the gate drive device 25b according to the present embodiment are denoted by the same reference numerals, and a description of the components will be omitted.

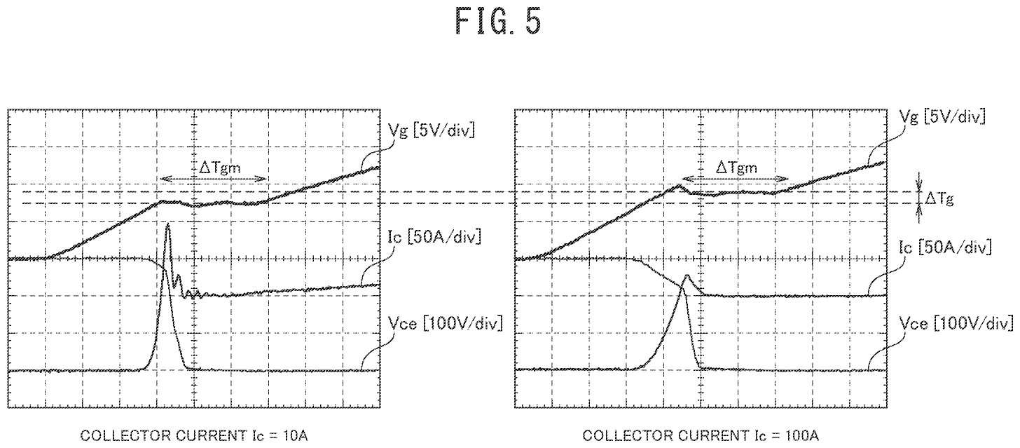

FIG. 5 is a diagram illustrating actual measurement values of drive waveforms in a case where the IGBT 22b is driven by the gate drive device 60. A left part of FIG. 5 illustrates the drive waveform in a case where a current value of the collector current flowing through the IBGT 22b is 10 A, and a right part of FIG. 5 illustrates the drive waveform in a case where a current value of the collector current flowing through the IBGT 22b is 100 A (a current of the absolute maximum rating). “Vg” illustrated in FIG. 5 represents a voltage waveform of the gate voltage Vg of the IGBT 22b, “Vice” illustrated in FIG. 5 represents a voltage waveform of the collector-emitter voltage of the IGBT 22b, and “Ic” illustrated in FIG. 5 represents a current waveform of the collector current flowing through the IGBT 22b. “ΔTgm” illustrated in FIG. 5 represents a mirror period.

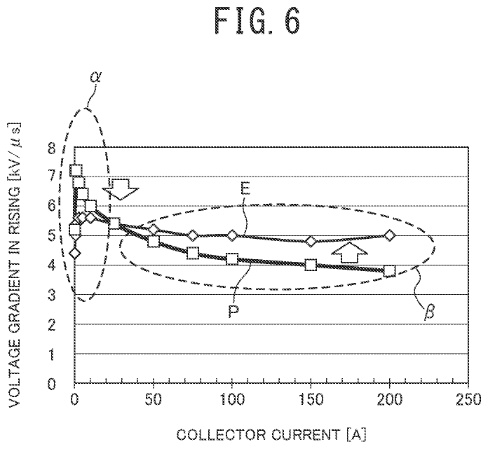

FIG. 6 is a graph illustrating a characteristic of the voltage gradient of the collector-emitter voltage of the IGBT with respect to the collector current flowing through the IGBT. In FIG. 6, a horizontal axis of the graph represents the collector current [A], and a vertical axis of the graph represents the voltage gradient [kV/μs] of the collector-emitter voltage in rising of the gate voltage. A curve E connecting diamond marks in FIG. 6 represents a voltage gradient characteristic of the gate drive device according to the present embodiment, and a curve P connecting square marks in FIG. 6 represents a voltage gradient characteristic of the gate drive device in the related art.

As illustrated in FIG. 4, the gate drive device 60 in the related art includes a gate signal generation unit 5 having the same configuration as the gate signal generation unit 5 included in the gate drive device 25b, and a DC signal generation unit 61. The DC signal generation unit 61 is configured with, for example, a ladder resistance circuit. The DC signal generation unit 61 has two resistance elements 611 and 612 connected in series between the power supply output terminal from which the power supply voltage VCC is output and the ground serving as the reference potential. One terminal of the resistance element 611 is connected to the power supply output terminal, and the other terminal of the resistance element 611 is connected to one terminal of the resistance element 612. The other terminal of the resistance element 612 is connected to the ground.

A connection portion between the resistance element 611 and the resistance element 612 is connected to the non-inversion input terminal (+) of the amplifier 51 included in the gate signal generation unit 5. Thus, a DC signal generated by the DC signal generation unit 61 is input to the amplifier 51. The gate signal generation unit 5 is configured to generate a gate signal based on the DC signal which is input to the amplifier 51 and output the gate signal to the gate of the IGBT 22b.

In the gate drive device 60, a voltage value of the DC signal which is input to the amplifier 51 is constant. Thus, the gate drive device 60 drives the IBGT 22b such that the same drive capability is obtained regardless of a level of the collector current flowing through the IGBT 22b.

As illustrated in FIG. 5, the voltage gradient dv/dt of the collector-emitter voltage is larger in a case where the current value of the collector current flowing through the IGBT 22b is small (the left part in FIG. 5) than in a case where the current value of the collector current flowing through the IGBT 22b is large (the right part in FIG. 5). Thus, rising of the collector current flowing through the IGBT 22b is faster in a case where the current value of the collector current flowing through the IGBT 22b is small than in a case where the current value of the collector current flowing through the IGBT 22b is large. For this reason, ringing occurs in the current waveform of the collector current having a small current value. As a result, the IGBT 22b generates a radiation noise, and is an electromagnetic-wave generation source.

Further, as illustrated in FIG. 5, the voltage level of the gate voltage Vg in the mirror period has a correlation relationship with the collector current flowing through the IGBT. Specifically, the voltage level of the gate voltage Vg in the mirror period is lower as the collector current flowing through the IGBT is smaller. In FIG. 5, a voltage difference in the voltage level of the gate voltage Vg in the mirror period is ΔTg between a case where a collector current of 100 A flows through the IGBT and a case where a collector current of 10 A flows through the IGBT. Therefore, in the present embodiment, by detecting the voltage level of the gate voltage Vg by using the correlation relationship between the voltage level of the gate voltage Vg in the mirror period and the collector current flowing through the IGBT, it is possible to control the voltage gradient dv/dt of the collector-emitter voltage of the IGBT according to the current amount of the collector current flowing through the IGBT.

The IGBT drive capability switching circuit 4 according to the present embodiment is capable of outputting the switching signal SS having the voltage value according to the current amount of the collector current flowing through the IGBT to the gate signal generation unit 5. The gate drive device 25b according to the present embodiment includes the IGBT drive capability switching circuit 4. Therefore, the gate drive device 25b is capable of generating the gate signal using the switching signal SS having the voltage value according to the current amount (current level) of the collector current flowing through the IGBT, and thus it is possible to optimize the drive capability of the IGBT according to a load state.

As illustrated in a portion of FIG. 6 surrounded by a broken line a, in a range in which the current amount of the collector current flowing through the IGBT is relatively small, the voltage gradient dv/dt of the collector-emitter voltage is smaller in the gate drive device according to the present embodiment than in the gate drive device in the related art. On the other hand, as illustrated in a portion of FIG. 6 surrounded by a broken line β, in a range in which the current amount of the collector current flowing through the IGBT is relatively large, the voltage gradient dv/dt of the collector-emitter voltage is larger in the gate drive device according to the present embodiment than in the gate drive device in the related art.

As described above, in the IGBT drive capability switching circuit 4 and the gate drive device 25b according to the present embodiment, it is possible to control the IGBT such that the drive capability is decreased in a case of a light load in which a current supplied to the load may be small. Further, in the IGBT drive capability switching circuit 4 and the gate drive device 25b, it is possible to control the IGBT such that the drive capability is increased in a case of a heavy load in which a current supplied to the load needs to be a large current.

As described above, the IGBT drive capability switching circuit according to the present embodiment includes the gate voltage detection unit that detects the voltage level of the gate voltage based on the gate signal which is input to the IGBT in the mirror period, and the gate signal switching unit that switches the voltage level of the gate signal based on the voltage level detected by the gate voltage detection unit. Further, the gate drive device according to the present embodiment includes the gate signal generation unit that generates the gate signal for driving the IGBT, and the IGBT drive capability switching circuit according to the present embodiment.

The drive capability of the IGBT changes according to the voltage level of the gate signal which is input to the gate. Therefore, in the gate drive device according to the present embodiment, by changing a gate charging current of the IGBT by detecting the gate voltage based on the gate signal which is input to the gate of the IGBT and switching the drive capability in a case where the voltage level of the gate voltage in the mirror period exceeds (or falls below) the setting voltage, it is possible to control the voltage gradient dv/dt of the collector-emitter voltage in switching of the IGBT.

The IGBT drive capability switching circuit and the gate drive device according to the present embodiment are capable of decreasing the voltage gradient dv/dt of the collector-emitter voltage of the IGBT by decreasing the drive capability in a state where the collector current flowing through the IGBT to be driven is small (a low current period). Further, the IGBT drive capability switching circuit and the gate drive device according to the present embodiment are capable of increasing the voltage gradient dv/dt of the collector-emitter voltage of the IGBT by improving the drive capability after the low current period and in a period for which the collector current flowing through the IGBT to be driven is increased. As described above, the IGBT drive capability switching circuit and the gate drive device according to the present embodiment are capable of optimizing a collector-current-dependent-characteristic of the voltage gradient dv/dt of the collector-emitter voltage of the IGBT, and suppressing a radiation noise while reducing a loss occurred in switching of the IGBT.

The present invention is not limited to the embodiment, and various modifications may be made.

The gate drive device according to the embodiment includes the comparison unit 411 for detecting the gate voltage with two setting voltages and the gate signal generation unit 5 for generating the gate signal having three voltage levels. However, the present invention is not limited to the configuration. For example, the comparison unit 411 may be configured to compare three or more setting voltages with the gate voltage, and the gate signal generation unit 5 may be configured to generate the gate signal having two voltage levels or four or more voltage levels. In this case, the IGBT drive capability switching circuit may include three or more comparators that compare the gate voltage Vg and the setting voltage Vst and a switching signal generation unit that generates the switching signal having two voltage levels or four or more voltage levels. Thus, the switching signal having two voltage levels or four or more voltage levels may be output to the gate signal generation unit. Therefore, the gate drive device is capable of switching the drive capability of the IGBT based on the gate signal having two voltage levels or four or more voltage levels.

In the embodiment, the switching signal generation unit 423 is configured to generate the selection signals Ss1, Ss2, and Ss3 having different voltage levels by resistance division using the resistance elements 423a, 423b, 423c, and 423d connected in series. However, the present invention is not limited to the configuration. For example, the switching signal generation unit may be configured with a plurality of operational amplifiers or a plurality of transistors capable of outputting DC signals having voltage levels different from each other.

In the embodiment, the IGBT drive capability switching circuit 4 is included in the gate drive device 25b. However, the IGBT drive capability switching circuit 4 may be included in the controller 26.

In the embodiment, the IGBT is described as an example of a semiconductor element. However, the present invention is not limited to the IGBT. The semiconductor element may be a wide-bandgap semiconductor element including SiC, GaN, diamond, a gallium-nitride-based material, a gallium-oxide-based material, AlN, AlGaN, ZnO, or the like, and a plurality of semiconductor elements including the materials may be appropriately combined.

The technical scope of the present invention is not limited to the exemplary embodiment illustrated and described, and is intended to include all embodiments that provide an effect equivalent to the object of the present invention. Further, the technical scope of the present invention is not limited to a combination of the features of the present invention described in the claims, and is defined by any desired combination of specific features of all the disclosed features.

### REFERENCE SIGNS LIST

4: IGBT drive capability switching circuit
5: gate signal generation unit
10: power converter
11: three-phase AC power supply
12: rectifier circuit
13: smoothing capacitor
15: three-phase AC motor
21: inverter circuit
22a, 22b, 22c, 22d, 22e, 22f: IGBT
23U: U-phase output arm
23V: V-phase output arm
23W: W-phase output arm
24a, 24b, 24c, 24d, 24e, 24f: flyback diode
25a, 25b, 25c, 25d, 25e, 25f, 60: gate drive device
26: controller
41: gate voltage detection unit
42: gate signal switching unit
43a: first logic circuit
43b: second logic circuit
45: filter unit
46: current detection unit
47: ladder resistance circuit
51: amplifier
52: current mirror circuit
53, 54, 55, 521, 522: transistor
56, 415, 423a, 423b, 423c, 423d, 461, 471, 472, 611, 612: resistance element
61: DC signal generation unit
221: current sense terminal
411: comparison unit
411a: first comparator
411b: second comparator
411c: third comparator
411d: first setting voltage generation unit
411e: second setting voltage generation unit
411f: third setting voltage generation unit
411g: capacitor
420: selection unit
421: control signal generation unit
422: switch circuit
422a, 422b, 422c: switching element
423: switching signal generation unit
451, 453: low-pass filter
452, 454: high-pass filter
Sc: switching signal
SC1: first comparison signal
SC2: second comparison signal
SC3: third comparison signal
SD1: first detection signal
SD2: second detection signal
Sg: gate signal
SH, SL, SM: selection control signal
So: output signal
SS: switching signal
Ss1, Ss2, Ss3: selection signal
Vg: gate voltage
Vin: input signal
Vst: setting voltage
Vst1: first setting voltage
Vst2: second setting voltage

1. A drive capability switching circuit for a semiconductor element, the circuit comprising:
a detection unit configured to detect a voltage level of a gate voltage based on a gate signal input to a voltage-controlled semiconductor element in a mirror period; and
a switching unit configured to switch a voltage level of the gate signal based on the voltage level detected by the detection unit.

2. The drive capability switching circuit for a semiconductor element according to claim 1, wherein
the detection unit has a comparison unit configured to compare the gate voltage in the mirror period with a setting voltage and compare a sense voltage with a setting voltage, the sense voltage being based on a sense current flowing through a current sense terminal of the voltage-controlled semiconductor element, and
the switching unit has a signal generation unit configured to generate a plurality of signals having different voltage levels and a selection unit configured to select the voltage level of the gate signal from the voltage levels of the plurality of signals based on a comparison result of the comparison unit.

3. The drive capability switching circuit for a semiconductor element according to claim 2, wherein
the comparison unit has a first comparator configured to compare the gate voltage in the mirror period with a first setting voltage as the setting voltage, a second comparator configured to compare the gate voltage in the mirror period with a second setting voltage as the setting voltage, and a third comparator configured to compare the sense voltage with a third setting voltage as the setting voltage, and
the detection unit has a first logic circuit configured to output, to the selection unit, a first detection signal obtained by performing a logic operation on a first comparison signal input from the first comparator and a third comparison signal input from the third comparator and a second logic circuit configured to output, to the selection unit, a second detection signal obtained by performing a logic operation on a second comparison signal input from the second comparator and the third comparison signal.

4. The drive capability switching circuit for a semiconductor element according to claim 3, wherein
the selection unit has a control signal generation unit configured to generate a control signal for controlling selection of any one of the plurality of signals using an input signal input to the gate signal generation unit configured to generate the gate signal, the first detection signal, and the second detection signal, and a switch circuit configured to output any one of the plurality of signals input from the signal generation unit by being controlled by the control signal to the gate signal generation unit.

5. A drive device for a semiconductor element, the device comprising:
a gate signal generation unit configured to generate a gate signal for driving a voltage-controlled semiconductor element; and
a drive capability switching circuit fora semiconductor element, the circuit including a detection unit configured to detect a voltage level of a gate voltage based on the gate signal in a mirror period and a switching unit configured to switch a voltage level of the gate signal based on the voltage level detected by the detection unit.

6. The drive device for a semiconductor element according to claim 5, wherein
the drive capability switching circuit for a semiconductor element is the drive capability switching circuit for a semiconductor element according to claim 2.

7. The drive device for a semiconductor element according to claim 5, wherein
the drive capability switching circuit for a semiconductor element is the drive capability switching circuit for a semiconductor element according to claim 3.

8. The drive device for a semiconductor element according to claim 5, wherein
the drive capability switching circuit for a semiconductor element is the drive capability switching circuit for a semiconductor element according to claim 4.
